(19) United States
(12) Patent Application Publication
(10) Pub. No.: US 2018/0302073 A1
(43) Pub. Date: Oct. 18, 2018

(54) DUTY CYCLE CALIBRATION CIRCUIT AND FREQUENCY SYNTHESIZER USING THE SAME

(71) Applicant: NOVATEK MICROELECTRONICS CORP., HsinChu (TW)

(72) Inventors: Po-Yao Ko, Hsinchu City (TW); Yi-Ming Wu, Kaohsiung City (TW)

(21) Appl. No.: 15/488,545

(22) Filed: Apr. 17, 2017

(51) Int. Cl. H03K 5/156; H03K 5/05; H03K 5/00

(52) U.S. Cl. CPC H03K 5/1565; H02M 3/07; H03K 5/00006; H03K 5/05

(57) ABSTRACT

A duty cycle calibration circuit and a frequency synthesizer using the same are provided. The duty cycle calibration circuit includes a single-ended correction circuit and a single-ended detection circuit. The single-ended correction circuit is configured to adjust a duty cycle of an input clock signal. The single-ended correction circuit includes a first slew rate controller, a second slew rate controller, and at least one logic gate. The first slew rate controller adjusts a rising slew rate of an output clock signal in response to a control signal. The second slew rate controller adjusts a falling slew rate of the output clock signal in response to the control signal. The single-ended detection circuit is configured to detect a duty cycle of the output clock signal by converting the duty cycle of the output clock signal to an average voltage to be served as the control signal.

### TECHNICAL FIELD

The disclosure relates in general to electronic circuits, and more particularly to a duty cycle calibration circuit and a frequency synthesizer that uses a duty cycle calibration circuit.

### BACKGROUND

Integrated circuit (IC) devices generally require a clock signal to operate. The clock signal enables synchronous communication between different modules in the IC device. Circuits that are designed to operate with a clock signal are generally activated at the rising or falling edge of the clock signal. Certain interfaces, such as the double data rate (DDR) memory interface, however, allow data transfer on both the rising and falling edges of the clock signal to achieve higher data transfer rates.

The clock signal continually transitions between logic high and logic low. The clock signal has a duty cycle representing the percentage of a clock period that the clock signal remains logic high or logic low. In applications such as double data rate systems, where both the rising and falling edges of the clock signal are used to sample data, it may be important to generate the clock signal having a duty cycle that is as close to 50% as possible (balanced duty cycle). The duty cycle of a clock signal may be distorted due to various phenomena such as mismatches in transistor devices. The clock signal with an unbalanced duty cycle may cause unwanted synchronization problems. Therefore there is a need for a duty cycle calibration circuit to generate a clock signal with a balanced duty cycle.

### SUMMARY

The disclosure is directed to a duty cycle calibration circuit and a frequency synthesizer using the same, such that a balanced duty cycle can be calibrated, and a wide calibration range can be achieved.

According to one embodiment of the invention, a duty cycle calibration circuit is provided. The duty cycle calibration circuit includes a single-ended correction circuit and a single-ended detection circuit. The single-ended correction circuit is configured to adjust a duty cycle of an input clock signal. The single-ended correction circuit includes a first slew rate controller, a second slew rate controller, and at least one logic gate. The first slew rate controller is configured to adjust a rising slew rate of an output clock signal in response to a control signal. The second slew rate controller is configured to adjust a falling slew rate of the output clock signal in response to the control signal. The at least one logic gate is coupled between the first slew rate controller and the second slew rate controller. The at least one logic gate is configured to generate the output clock signal in response to the input clock signal. The single-ended detection circuit is configured to detect a duty cycle of the output clock signal by converting the duty cycle of the output clock signal to an average voltage to be served as the control signal.

According to one embodiment of the invention, a duty cycle calibration circuit is provided. The duty cycle calibration circuit includes a single-ended correction circuit and a single-ended detection circuit. The single-ended correction circuit is configured to adjust a duty cycle of an input clock signal in response to a control signal to generate an output clock signal. The single-ended correction circuit adjusts the duty cycle of the input clock signal by adjusting a slew rate of the output clock signal in response to the control signal. The single-ended detection circuit is configured to detect a duty cycle of the output clock signal by converting the duty cycle of the output clock signal to an average voltage to be served as the control signal.

According to one embodiment of the invention, a frequency synthesizer is provided. The frequency synthesizer includes a frequency multiplier and a duty cycle calibration circuit. The frequency multiplier is configured to increase a frequency of a first clock signal to generate a second clock signal. The duty cycle calibration circuit includes a single-ended correction circuit and a single-ended detection circuit. The single-ended correction circuit is configured to adjust a duty cycle of the second clock signal. The single-ended correction circuit includes a first slew rate controller, a second slew rate controller, and at least one logic gate. The first slew rate controller is configured to adjust a rising slew rate of an output clock signal in response to a control signal. The second slew rate controller is configured to adjust a falling slew rate of the output clock signal in response to the control signal. The at least one logic gate is coupled between the first slew rate controller and the second slew rate controller. The at least one logic gate is configured to generate the output clock signal in response to the second clock signal. The single-ended detection circuit is configured to detect a duty cycle of the output clock signal by converting the duty cycle of the output clock signal to an average voltage to be served as the control signal.

According to one embodiment of the invention, a frequency synthesizer is provided. The frequency synthesizer includes a first duty cycle calibration circuit and a frequency multiplier. The first duty cycle calibration circuit includes a first single-ended correction circuit and a first single-ended detection circuit. The first single-ended correction circuit is configured to adjust a duty cycle of an input clock signal. The first single-ended correction circuit includes a first slew rate controller, a second slew rate controller, and at least one logic gate. The first slew rate controller is configured to adjust a rising slew rate of a first clock signal in response to a first control signal. The second slew rate controller is configured to adjust a falling slew rate of the first clock signal in response to the first control signal. The at least one logic gate is coupled between the first slew rate controller and the second slew rate controller. The at least one logic gate is configured to generate the first clock signal in response to the input clock signal. The first single-ended detection circuit is configured to detect a duty cycle of the first clock signal by converting the duty cycle of the first clock signal to an average voltage to be served as the first control signal. The frequency multiplier is configured to increase a frequency of the first clock signal to generate a second clock signal.

The invention will become apparent from the following detailed description of the non-limiting embodiments. The following description is made with reference to the accompanying drawings.

### BRIEF DESCRIPTION OF THE DRAWINGS

FIG. 1A shows a diagram illustrating a duty cycle calibration circuit according to one embodiment of the invention.

FIG. 1B shows a diagram illustrating a duty cycle calibration circuit according to one embodiment of the invention.

FIG. 2A shows a diagram illustrating a single-ended correction circuit according to one embodiment of the invention.

FIG. 2B shows a diagram illustrating a single-ended correction circuit according to one embodiment of the invention.

FIGS. 3A-3D show diagrams illustrating different implementations of a single-ended detection circuit according to embodiments of the invention.

FIG. 4 shows a diagram illustrating a duty cycle calibration circuit according to one embodiment of the invention.

FIG. 5 shows an example waveform of duty cycle calibration for an input clock signal with duty cycle less than 50%.

FIG. 6 shows an example waveform of duty cycle calibration for an input clock signal with duty cycle greater than 50%.

FIG. 7 shows a diagram illustrating a frequency synthesizer according to one embodiment of the invention.

FIG. 8A shows a diagram illustrating a frequency multiplier according to one embodiment of the invention.

FIG. 8B shows an example waveform of the frequency multiplier shown in FIG. 8A.

FIG. 9 shows a diagram illustrating a frequency synthesizer according to one embodiment of the invention.

FIG. 10 shows a diagram illustrating a frequency synthesizer according to one embodiment of the invention.

FIG. 11 shows an example waveform of the frequency synthesizer shown in FIG. 10.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

In one embodiment, a duty cycle calibration circuit is disclosed. The duty cycle calibration circuit includes a single-ended correction circuit, configured to adjust a duty cycle of an input clock signal and a single-ended detection circuit, configured to detect a duty cycle of an output clock signal by converting the duty cycle of the output clock signal to an average voltage to be served as the control signal. The single-ended correction circuit can adjust the duty cycle of the input clock signal by adjusting a slew rate of the output clock signal in response to the control signal. In one embodiment, The single-ended correction circuit may include a first slew rate controller, configured to adjust a rising slew rate of the output clock signal in response to a control signal; a second slew rate controller, configured to adjust a falling slew rate of the output clock signal in response to the control signal; and at least one logic gate coupled between the first slew rate controller and the second slew rate controller, configured to generate the output clock signal in response to the input clock signal.

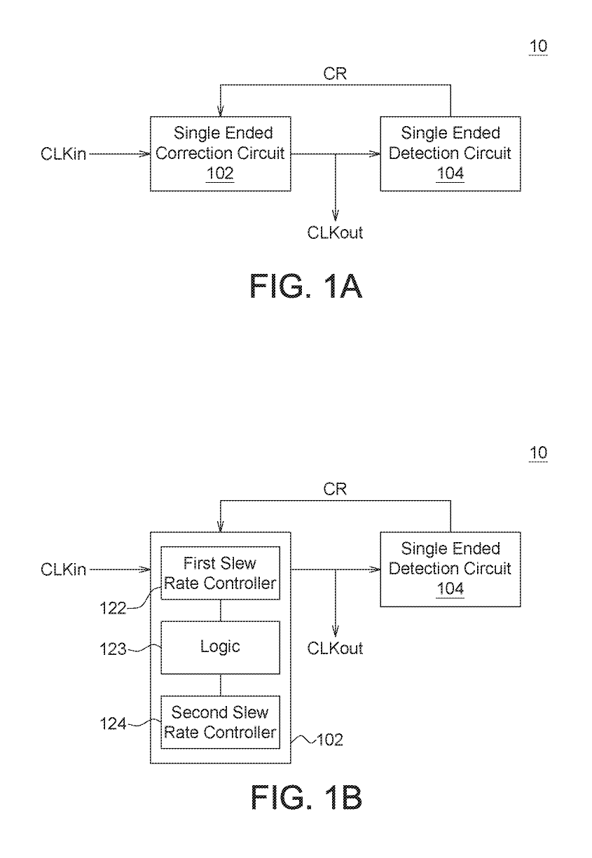

FIG. 1A shows a diagram illustrating a duty cycle calibration circuit 10 according to one embodiment of the invention. The duty cycle calibration circuit 10 includes a single-ended correction circuit 102 and a single-ended detection circuit 104. The single-ended correction circuit 102 is configured to adjust a duty cycle of an input clock signal CLKin in response to a control signal CR to generate an output clock signal CLKout. The single-ended correction circuit 102 adjusts the duty cycle of the input clock signal CLKin by adjusting a slew rate of the output clock signal CLKout in response to the control signal CR. The single-ended detection circuit 104 is configured to detect a duty cycle of the output clock signal CLKout by converting the duty cycle of the output clock signal CLKout to an average voltage to be served as the control signal CR.

As shown in FIG. 1A, the single-ended correction circuit 102 and the single-ended detection circuit 104 both use single-ended signaling. For example, electrical signal carrying a varying voltage is transmitted over a single wire. The advantage of single-ended signaling over differential signaling is that fewer wires are needed, thus reducing the circuit area. An example implementation of the single-ended correction circuit 102 that is capable of adjusting the slew rate of the output clock signal CLKout may be referred to FIG. 1B.

FIG. 1B shows a diagram illustrating a duty cycle calibration circuit 10 according to one embodiment of the invention. The duty cycle calibration circuit 10 includes a single-ended correction circuit 102 and a single-ended detection circuit 104. The single-ended correction circuit 102 is configured to adjust a duty cycle of an input clock signal CLKin. The single-ended correction circuit 102 includes a first slew rate controller 122, a second slew rate controller 124, and a logic block 123 which includes at least one logic gate. The first slew rate controller 122 is configured to adjust a rising slew rate of an output clock signal CLKout in response to a control signal CR. The second slew rate 124 controller is configured to adjust a falling slew rate of the output clock signal CLKout in response to the control signal CR. The logic block 123 which includes at least one logic gate is coupled between the first slew rate controller 122 and the second slew rate controller 124. The at least one logic gate is configured to generate the output clock signal CLKout in response to the input clock signal CLKin. The single-ended detection circuit 104 is configured to detect a duty cycle of the output clock signal CLKout by converting the duty cycle of the output clock signal CLKout to an average voltage to be served as the control signal CR.

As shown in FIG. 1A and FIG. 1B, the single-ended correction circuit 102 and the single-ended detection circuit 104 constitute a feedback loop, where the single-ended correction circuit 102 is controlled by the control signal CR, and the single-ended detection circuit 104 generates the control signal CR in response to the output clock signal CLKout provided by the single-ended correction circuit 102. In one embodiment, the single-ended correction circuit 102 includes a single-ended current starving inverter. The output slew rate of the single-ended current starting inverter may be controlled by the control signal CR. In one embodiment, the logic block 123 may include an inverter 110. The output slew rate of the inverter 110 or an alternative logic gate inside the logic block 123 may be controlled by the control signal CR such that the duty cycle of the output clock signal CLKout may be adjusted. The description given below uses the inverter 110 as an example for the logic block 123. The output slew rate of the inverter 110 may refer to how fast the output signal generated by the inverter 110 rises from logic low to logic high and/or falls from logic high to logic low. By changing the output slew rate of the inverter 110, the time period that the output clock signal CLKout remains logic high (or logic low) may be changed accordingly, hence adjusting the duty cycle of the output clock signal CLKout. Moreover, because the single-ended detection circuit 104 is configured to detect the duty cycle of the output clock signal CLKout, the single-ended detection circuit 104 may obtain information regarding how much the current duty cycle deviates from the balanced duty cycle, and thus the single-ended detection circuit 104 is capable of generating the appropriate control signal CR based on such information to facilitate duty cycle adjustment in the single-ended correction circuit 102.

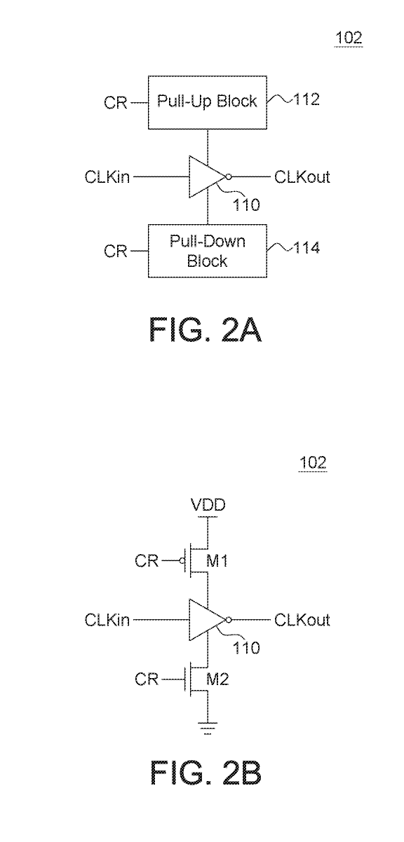

There may be several different implementations for the single-ended correction circuit 102 and the single-ended detection circuit 104, and some embodiments are given below. FIG. 2A shows a diagram illustrating a single-ended correction circuit according to one embodiment of the invention. In this embodiment, the single-ended correction circuit 102 includes an inverter 110, a pull-up block 112, and a pull-down block 114. The pull-up block 112 is coupled to the control signal CR. The pull-up block 112 affects the rising slew rate of the inverter 110. The pull-down block 114 is coupled to the control signal CR. The pull-down block 114 affects the falling slew rate of the inverter 110. The inverter 110 is coupled between the pull-up block 112 and the pull-down block 114, and is configured to generate the output clock signal CLKout in response to the input clock signal CLKin. The pull-up block 112 and the pull-down block 114 may be implemented by active and/or passive circuit elements, such as transistors and/or resistors.

FIG. 2B shows a diagram illustrating a single-ended correction circuit 102 according to one embodiment of the invention. In this embodiment, the single-ended correction circuit 102 includes an inverter 110, a pull-up transistor M1 and a pull-down transistor M2. Refer to FIG. 2A, in this embodiment, the pull-up block 112 includes the pull-up transistor M1, and the pull-down block 114 includes the pull-down transistor M2. The pull-up transistor M1 is coupled to the control signal CR and the inverter 110. The pull-up transistor M1 is configured to adjust a rising slew rate of the inverter 110. The pull-down transistor M2 is coupled to the control signal CR and the inverter 110. The pull-down transistor M2 is configured to adjust a falling slew rate of the inverter 110. For example, when the control signal CR is a lower voltage, the effective resistance of the pull-down transistor M2 becomes larger, and hence the falling slew rate of the inverter 110 decreases. On the other hand, when the control signal CR is a higher voltage, the effective resistance of the pull-up transistor M1 becomes larger, and hence the rising slew rate of the inverter 110 decreases. The output of the inverter 110 may be directly coupled to the output clock signal CLKout, or there may be other circuit devices coupled between the output of the inverter 110 and the output clock signal CLKout.

In one embodiment, the pull-up transistor M1 is a P-type metal-oxide-semiconductor (PMOS) transistor, having a gate terminal coupled to the control signal CR, a drain terminal coupled to the inverter 110, and a source terminal coupled to a power supply (VDD shown in FIG. 2B). The pull-down transistor M2 is a N-type metal-oxide-semiconductor (NMOS) transistor, having a gate terminal coupled to the control signal CR, a drain terminal coupled to the inverter 110, and a source terminal coupled to a reference voltage terminal, such as the ground voltage as shown in FIG. 2B. The embodiment using PMOS transistor and NMOS transistor as shown in FIG. 2B is merely exemplary rather than limiting. Other types of pull-up transistor and pull-down transistor are also applicable, such as bipolar junction transistors (BJT).

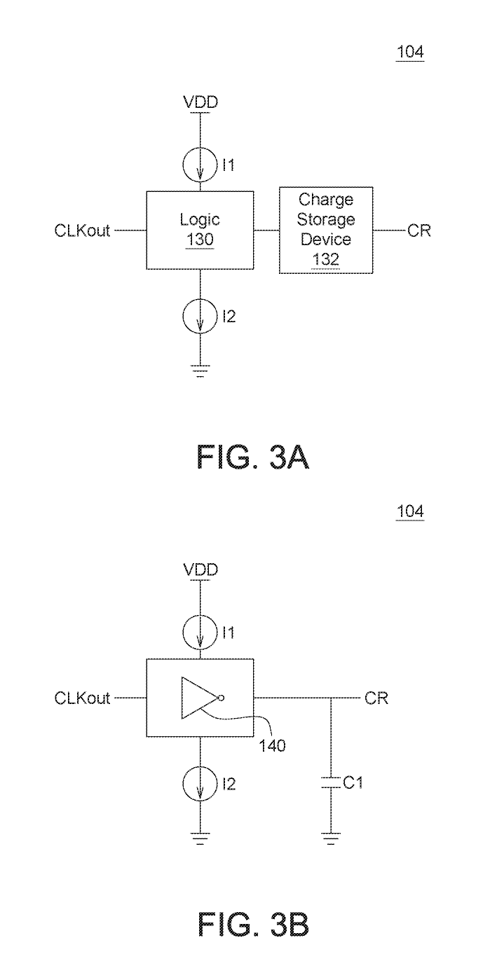

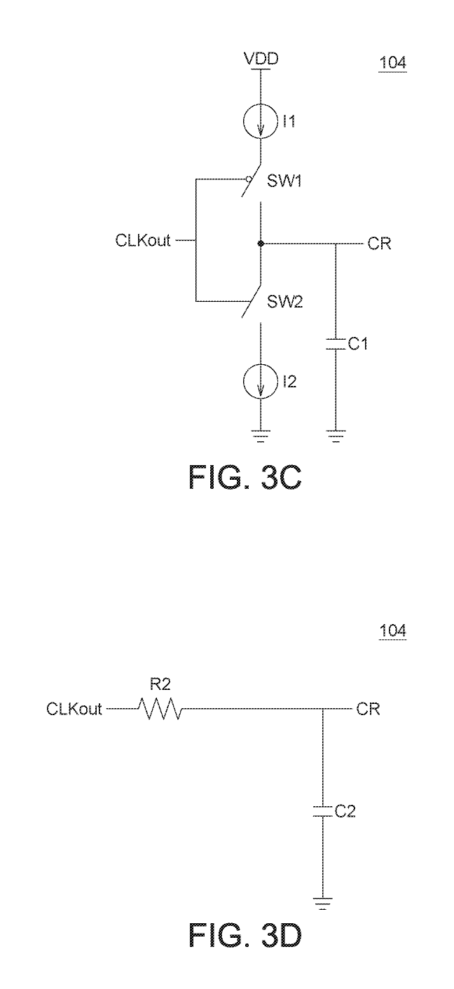

In one embodiment, the single-ended detection circuit 104 may include a charge pump. FIG. 3A shows a diagram illustrating a single-ended detection circuit 104 according to one embodiment of the invention. An example charge pump circuit is shown in FIG. 3A. The charge pump includes a charge storage device 132, a first current source 11, a second current source 12, and a logic block 130 including at least one logic gate. The charge storage device 132 is configured to generate the control signal CR. The charge storage device 132 may include a capacitor. The first current source 11 is configured to provide a charging current for the charge storage device 132. The second current source 12 is configured to provide a discharging current for the charge storage device 132. The logic block 130 is coupled between the first current source 11 and the second current source 12. The logic block 130 is coupled to the charge storage device 132 to generate the control signal CR in response to the output clock signal CLKout.

FIG. 3B shows a diagram illustrating a single-ended detection circuit 104 according to an embodiment of the invention. In this embodiment the charge storage device 132 is a capacitor C1. The logic block 130 includes an inverter 140. For example, when the output clock signal CLKout is logic low, the first current source 11 charges the capacitor C1. On the other hand, when the output clock signal CLKout is logic high, the second current source 12 discharges the capacitor C1.

FIG. 3C shows a diagram illustrating a single-ended detection circuit 104 according to an embodiment of the invention. In this embodiment, the single-ended detection circuit 104 includes a capacitor C1, a first current source 11, a second current source 12, a first switch device SW1, and a second switch device SW2. The capacitor C1 is configured to provide the control signal CR. The first current source 11 is configured to provide a charging current for the capacitor C1. The second current source 12 is configured to provide a discharging current for the capacitor C1. The first switch device SW1 is coupled between the first current source 11 and the capacitor C1, wherein the first switch device SW1 is switched under control of the output clock signal CLKout. The second switch device SW2 is coupled between the second current source 12 and the capacitor C1, wherein the second switch device SW2 is switched under control of the output clock signal CLKout.

The first switch device SW1 and the second switch device SW2 may be both controlled by the output clock signal CLKout, but the first switch device SW1 and the second switch device SW2 may possess opposite polarities. For example, one of the switches may be active-high and the other may be active-low. In the embodiment shown in FIG. 3C, when the output clock signal CLKout is at logic low level, the first switch device SW1 turns on and the second switch device SW2 turns off, charging the capacitor C1 by the first current source 11. When the output clock signal CLKout is at logic high level, the first switch device SW1 turns off and the second switch device SW2 turns on, discharging the capacitor C1 by the second current source 12. As such, by alternately charging and discharging the capacitor C1, the voltage level at the capacitor C1 is affected by the duty cycle of the output clock signal CLKout. For instance, the first current source 11 and the second current source 12 may be set as equal magnitude, then the voltage level at the capacitor C1 continues to increase if the duty cycle of the output clock signal CLKout is lower than 50%, the voltage level at the capacitor C1 continues to decrease if the duty cycle of the output clock signal CLKout is higher than 50%, and the voltage level at the capacitor C1 remains constant when the duty cycle of the output clock signal CLKout is equal to 50%.

FIG. 3D shows a diagram illustrating a single-ended detection circuit 104 according to an embodiment of the invention. In this embodiment, the single-ended detection circuit 104 includes an RC circuit, which includes a resistor R2 and a capacitor C2. The RC circuit constitutes a low-pass filter circuit, effectively converting the duty cycle of the output clock signal CLKout to an average voltage. FIG. 3D illustrates one possible implementation for a low-pass filter circuit. Other types of RC circuit with similar frequency response characteristic may also be applicable for the single-ended detection circuit 104.

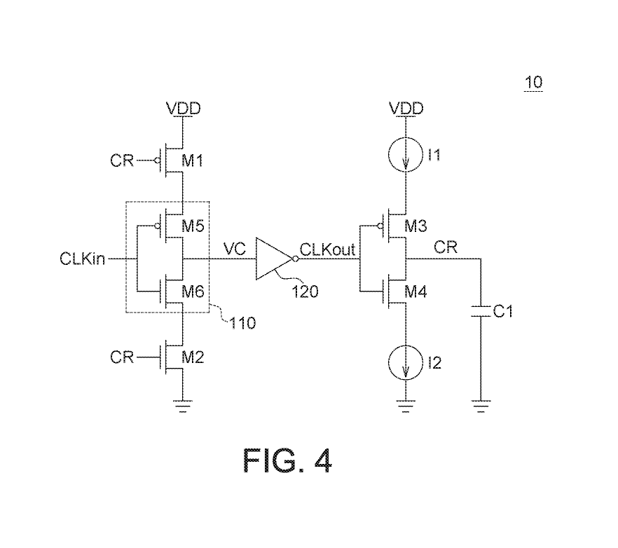

FIG. 4 shows a diagram illustrating a duty cycle calibration circuit 10 according to one embodiment of the invention. In this embodiment, the first switch device SW1 includes a PMOS transistor M3, having a gate terminal coupled to the output clock signal CLKout, a drain terminal coupled to the capacitor C1, and a source terminal coupled to the first current source 11, and the second switch device SW2 includes a NMOS transistor M4, having a gate terminal coupled to the output clock signal CLKout, a drain terminal coupled to the capacitor C1, and a source terminal coupled to the second current source 12. Of course the embodiment using PMOS transistor and NMOS transistor as the switch devices is merely exemplary rather than limiting. Other types of switches are also applicable, such as BJT and CMOS transmission gate. The first switch device SW1 and the second switch device SW2 may be designed to be triggered by signals with different polarities. The inverter 110 is implemented by a PMOS transistor M5 and a NMOS transistor M6. The single-ended correction circuit 102 also includes a second inverter 120 cascaded to the inverter 110 for generating the output clock signal CLKout. Refer to FIG. 1B, the logic block 123 may include the inverter 110 and the second inverter 120. The second inverter 120 is coupled between the inverter 110 and the single-ended detection circuit 104. Note that the second inverter 120 in this embodiment may be replaced by a buffer circuit. For example, the buffer circuit may be a single transistor buffer, a single inverter, an inverter chain with multiple inverters, an operational amplifier based buffer, or other types of buffer circuit implementations. In an alternative embodiment, the output of the second inverter 120 may be directly coupled to the transistors M3 and M4 in the single-ended detection circuit 104, and additional buffer element(s) may be added as a fan-out branch at the output of the second inverter 120 for generating the output clock signal CLKout.

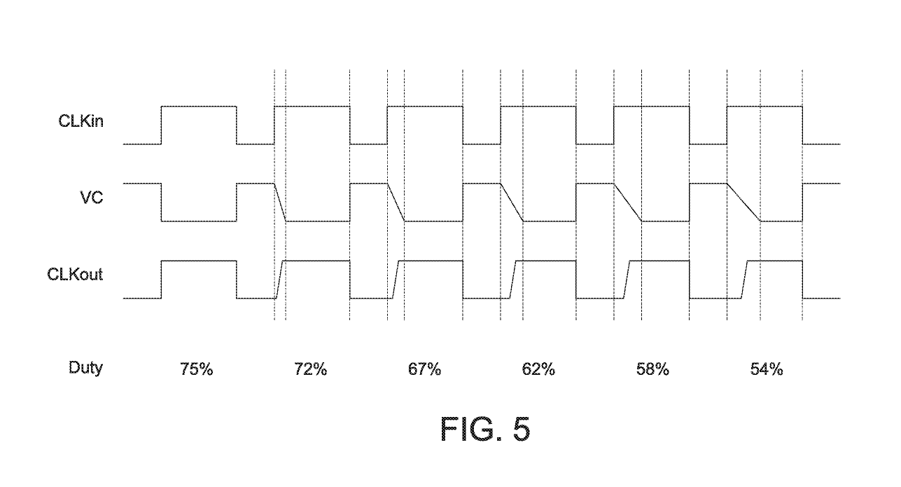

FIG. 5 shows an example waveform of duty cycle calibration for an input clock signal with duty cycle less than 50%. The signal VC is the voltage level at the output of the inverter 110. As shown in FIG. 5, initially the signal VC is an inverted version of the input clock signal CLKin, and the output clock signal CLKout is substantially the same (ignoring gate propagation delay of inverters) as the input clock signal CLKin having duty cycle greater than 50% (75% for example). According to the circuit structure of the single-ended detection circuit 104, the voltage level of the control signal CR decreases in response to the output clock signal CLKout (because discharging time is longer than charging time). Consequently, the effective resistance of the pull-down transistor M2 becomes larger, and hence the falling slew rate of the inverter 110 decreases. As can be seen in the second cycle in FIG. 5, the signal VC falls from logic high to logic low with a decreased falling slew rate. After the signal VC passes through the second inverter 120, the output clock signal CLKout now has a decreased duty cycle (as compared to the first cycle shown in FIG. 5). The above described procedure will be executed repeatedly because of the feedback loop in the duty cycle calibration circuit 10. That is, the falling slew rate of the inverter 110 will gradually decrease, and thus the duty cycle of the output clock signal CLKout will gradually decrease in each subsequent clock cycle (in the example shown in FIG. 5, the duty cycle in each successive cycle is 75%, 72%, 67%, 62%, . . . ) and eventually reaches 50%, making the control signal CR stable and the slew rate of the inverter 110 stable as well. Note that the values of the duty cycle depicted in FIG. 5 are merely examples. The actual decreasing rate of the duty cycle may be faster or slower depending on the circuit design parameters.

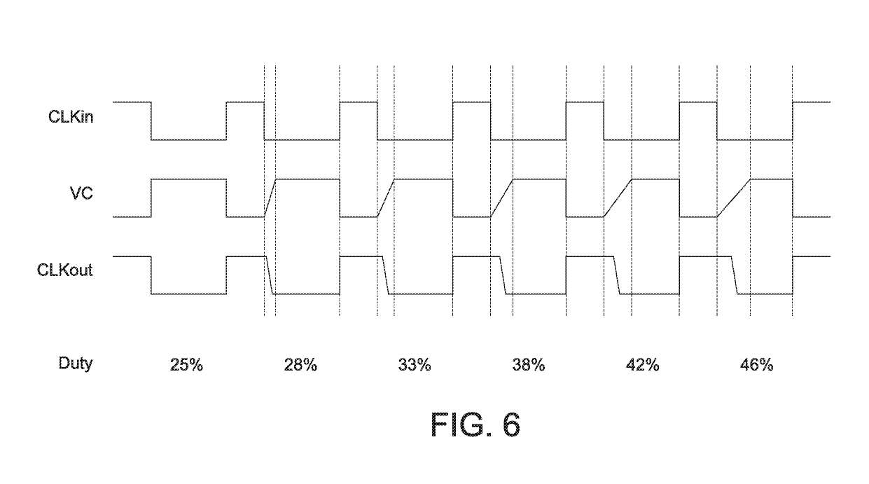

FIG. 6 shows an example waveform of duty cycle calibration for an input clock signal with duty cycle greater than 50%. As shown in FIG. 6, initially the output clock signal CLKout is substantially the same as the input clock signal CLKin having duty cycle less than 50% (25% for example). According to the circuit structure of the single-ended detection circuit 104, the voltage level of the control signal CR increases in response to the output clock signal CLKout (because charging time is longer than discharging time). Consequently, the effective resistance of the pull-up transistor M1 becomes larger, and hence the rising slew rate of the inverter 110 decreases. As can be seen in the second cycle in FIG. 6, the signal VC rises from logic low to logic high with a decreased rising slew rate. After the signal VC passes through the second inverter 120, the output clock signal CLKout now has an increased duty cycle (as compared to the first cycle shown in FIG. 6). The above described procedure will be executed repeatedly. That is, the rising slew rate of the inverter 110 will gradually decrease, and thus the duty cycle of the output clock signal CLKout will gradually increase in each subsequent clock cycle (in the example shown in FIG. 6, the duty cycle in each successive cycle is 25%, 28%, 33%, 38%, . . . ) and eventually reaches 50%, making the control signal CR stable and the slew rate of the inverter 110 stable as well.

According to the duty cycle calibration circuit in the above embodiments, the circuit implementation is simple, and therefore the required hardware area is small and the power consumption is also low. Moreover, because of the simple circuit structure and the feedback loop, the proposed duty cycle calibration circuit has short response time, which represents the time required for the output clock signal to reach 50% duty cycle starting from the initial state. By employing transistors and switches with different polarities (such as PMOS transistor and NMOS transistor in the embodiments), there is no need for generating differential signals. A common signal can be fed to switches with different polarities to achieve the calibration function. In addition, the proposed duty cycle calibration circuit is able to calibrate an input clock signal with a duty cycle ranging from 5%-95% according to circuit simulation and measurement result. Thus the proposed duty cycle calibration circuit can be easily integrated with other circuit devices because of the wide calibration range. Several embodiments regarding combining the duty calibration circuit with other modules are given below.

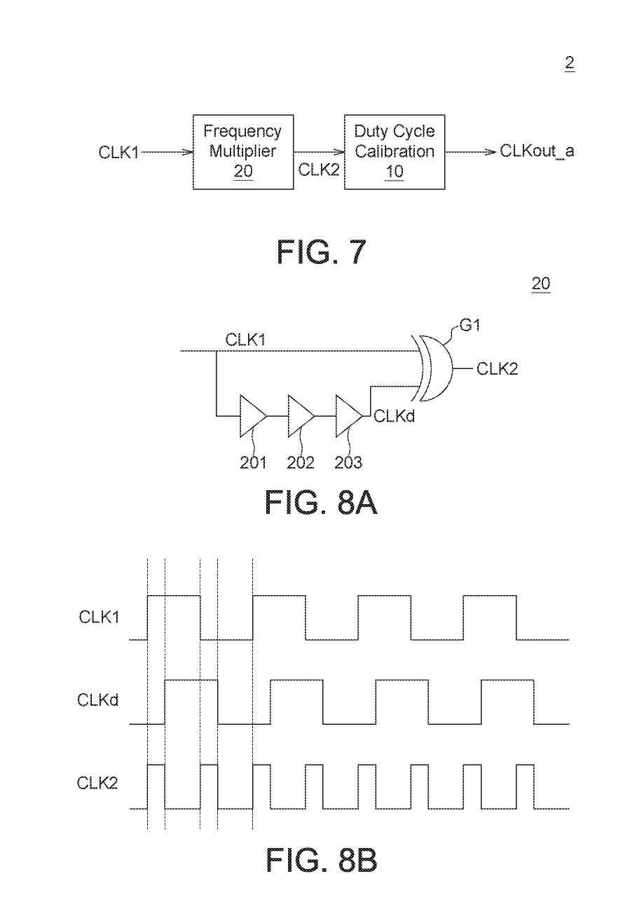

A frequency synthesizer is an electronic device for generating a signal having a desired frequency. The frequency synthesizer has been widely used in many modern electronic devices, such as radio receivers and mobile phones. FIG. 7 shows a diagram illustrating a frequency synthesizer 2 according to one embodiment of the invention. The frequency synthesizer 2 includes a frequency multiplier 20 and a duty cycle calibration circuit 10. The frequency multiplier 20 is configured to increase a frequency of a first clock signal CLK1 to generate a second clock signal CLK2. The duty cycle calibration circuit 10 may be referred to embodiments shown in FIG. 1A-FIG. 4. For example, the duty cycle calibration circuit 10 includes a single-ended correction circuit 102 and a single-ended detection circuit 104. The single-ended correction circuit 102 is configured to adjust a duty cycle of the second clock signal CLK2 in response to a control signal CR to generate an output clock signal CLKout_a. The single-ended detection circuit 104 is configured to detect a duty cycle of the output clock signal CLKout_a to generate the control signal CR. The single-ended correction circuit 102 includes an inverter 110 coupled to the control signal CR, and the control signal CR is configured to adjust an output slew rate of the inverter 110.

The second clock signal CLK2 generated by the frequency multiplier 20 may have a second frequency that is a multiple of a first frequency of the first clock signal CLK1. A frequency doubler (the second frequency is twice of the first frequency) is taken as a representative example for the frequency multiplier 20 in the following embodiments. Of course the frequency multiplier 20 is not limited to a frequency doubler.

As mentioned above, because the duty cycle calibration circuit 10 has a wide calibration range, the duty cycle of the second clock signal CLK2 generated by the frequency multiplier 20 does not have to be close to 50%. In other words, even if the second clock signal CLK2 has a duty cycle being 80% or 20%, the duty cycle calibration circuit 10 can make the output clock signal CLKout_a have a duty cycle close to 50%. Therefore the frequency multiplier 20 in the frequency synthesizer 2 can be realized by a simple circuit, without worrying the quality of the output duty cycle.

FIG. 8A shows a diagram illustrating a frequency multiplier 20 according to one embodiment of the invention. The frequency multiplier 20 includes a XOR logic gate G1, having a first input terminal coupled to the first clock signal CLK1, a second input terminal coupled to a delayed version of the first clock signal CLKd, and an output terminal coupled to the second clock signal CLK2. The delayed version of the first clock signal CLKd may be generated by one or more delay elements 201-203 (such as buffers and/or inverters) connected in series. FIG. 8B shows an example waveform of the frequency multiplier shown in FIG. 8A. By performing a logical XOR operation on the first clock signal CLK1 and the delayed version of the first clock signal CLKd, the second clock signal has a doubled frequency as compared to the first clock signal CLK1. The duty cycle of the second clock signal CLK2 depends on the delay amount introduced by the delay elements 201-203. The frequency multiplier 20 in this embodiment has the advantages of small circuit area, low power consumption, and ease of integration.

Because the output clock signal CLKout_a generated by the frequency synthesizer 2 has a balanced duty cycle, the frequency synthesizer 2 is suitable for DDR memory applications, where both the rising edge and the falling edge of the clock signal are important. There are some applications where the frequency matters more than the balanced duty cycle, and therefore another embodiment for combining the duty calibration circuit 10 and the frequency multiplier 20 is given below.

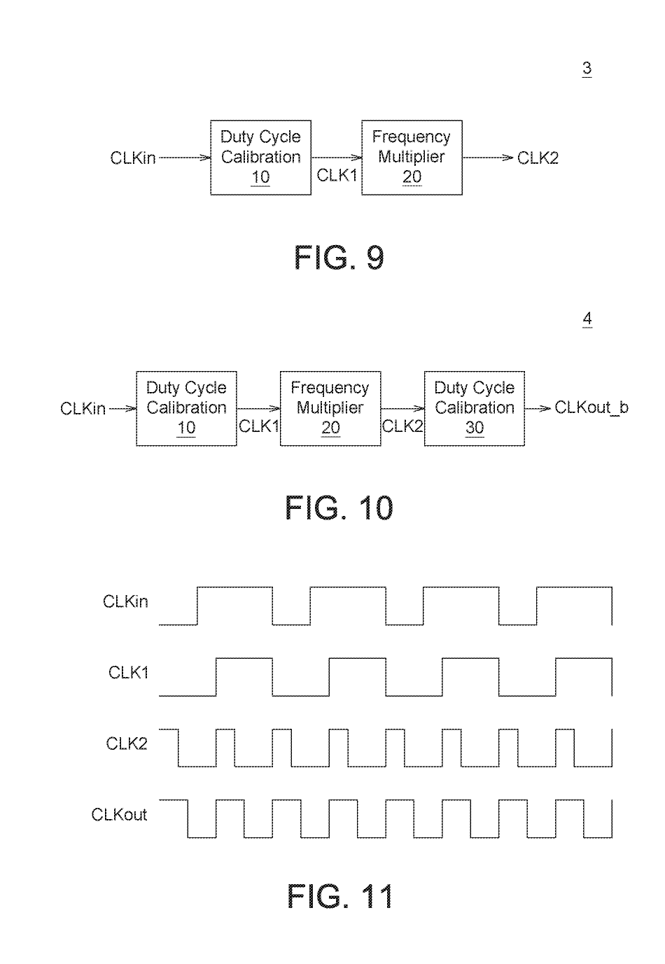

FIG. 9 shows a diagram illustrating a frequency synthesizer 3 according to one embodiment of the invention. The frequency synthesizer 3 includes a duty cycle calibration circuit 10 and a frequency multiplier 20. The connection order in this embodiment is reversed as compared to that shown in FIG. 7. The duty cycle calibration circuit 10 may be referred to embodiments shown in FIG. 1A-FIG. 4. For example, the duty cycle calibration circuit 10 includes a single-ended correction circuit 102 and a single-ended detection circuit 104. The single-ended correction circuit 102 is configured to adjust a duty cycle of an input clock cycle in response to a control signal CR to generate a first clock signal CLK1. The single-ended detection circuit 104 is configured to detect a duty cycle of the first clock signal CLK1 to generate the control signal CR. The single-ended correction circuit 102 includes an inverter 110 coupled to the control signal CR, and the control signal CR is configured to adjust an output slew rate of the inverter 110. The frequency multiplier 20 is configured to increase a frequency of the first clock signal CLK1 to generate a second clock signal CLK2.

In the configuration shown in FIG. 9, because the duty cycle calibration circuit 10 is configured to receive the input clock signal CLKin, there is a wider tolerable range for the duty cycle of the input clock signal CLKin as compared to the configuration shown in FIG. 7. Specifically, even if the input clock signal CLKin in FIG. 9 does not have a balanced duty cycle, the duty cycle calibration circuit 10 makes the first clock signal CLK1 have a balanced duty cycle, which in turn enables the frequency multiplier 20 to be implemented by simple hardware, such as the embodiment shown in FIG. 8A. The second clock signal CLK2 in FIG. 9 might not have a balanced duty cycle. Therefore the frequency synthesizer 3 is suitable for applications where either the rising edge or the falling edge matters, such as a frequency synthesizer adapted for a wireless transceiver.

FIG. 10 shows a diagram illustrating a frequency synthesizer 4 according to one embodiment of the invention. As compared to the embodiment shown in FIG. 9, the frequency synthesizer 4 further includes a second duty cycle calibration circuit 30, which may be referred to embodiments shown in FIG. 1A-FIG. 4. For example, the second duty cycle calibration circuit 30 includes a second single-ended correction circuit and a second single-ended detection circuit. The second single-ended correction circuit is configured to adjust a duty cycle of the second clock signal CLK2 in response to a second control signal to generate an output clock signal CLKout_b. The second single-ended correction circuit adjusts the duty cycle of the second clock signal CLK2 by adjusting a slew rate of the output clock signal CLKout_b in response to the second control signal. The second single-ended detection circuit is configured to detect a duty cycle of the output clock signal CLKout_b to an average voltage to be served as the second control signal. This additional second duty cycle calibration circuit 30 makes the output clock signal CLKout_b have a balanced duty cycle.

FIG. 11 shows an example waveform of the frequency synthesizer shown in FIG. 10. The input clock signal CLKin has for example a 67% duty cycle. After the duty cycle calibration circuit 10, the first clock signal CLK1 has a 50% duty cycle. Then the frequency multiplier 20 makes the second clock signal CLK2 have frequency twice of the first clock signal CLK1. The second clock signal CLK2 has for example a 35% duty cycle. After the second duty cycle calibration circuit 30, the output clock signal CLKout_b has a 50% duty cycle. The frequency of the output clock signal CLKout_b is doubled as compared to that of the input clock signal CLKin.

As shown in the above embodiments, the frequency multiplier and the duty cycle calibration circuit can be easily integrated. The connection order and the exact number of modules used can be adjusted according to design requirements and applications. Because the wide calibration range that can be achieved by the duty cycle calibration circuit, the frequency multiplier has great design flexibility and less constraint on duty cycle, making it easier to save hardware cost and reduce power consumption in the frequency multiplier.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A duty cycle calibration circuit, comprising:
a single-ended correction circuit, configured to adjust a duty cycle of an input clock signal, the single-ended correction circuit comprising:
a first slew rate controller, configured to adjust a rising slew rate of an output clock signal in response to a control signal;
a second slew rate controller, configured to adjust a falling slew rate of the output clock signal in response to the control signal; and
at least one logic gate coupled between the first slew rate controller and the second slew rate controller, configured to generate the output clock signal in response to the input clock signal; and
a single-ended detection circuit, configured to detect a duty cycle of the output clock signal by converting the duty cycle of the output clock signal to an average voltage to be served as the control signal.

2. The duty cycle calibration circuit according to claim 1, wherein the single-ended detection circuit comprises a charge pump.

3. The duty cycle calibration circuit according to claim 1, wherein the at least one logic gate comprises an inverter.

4. A duty cycle calibration circuit, comprising:
a single-ended correction circuit, configured to adjust a duty cycle of an input clock signal in response to a control signal to generate an output clock signal, wherein the single-ended correction circuit adjusts the duty cycle of the input clock signal by adjusting a slew rate of the output clock signal in response to the control signal; and
a single-ended detection circuit, configured to detect a duty cycle of the output clock signal by converting the duty cycle of the output clock signal to an average voltage to be served as the control signal.

5. The duty cycle calibration circuit according to claim 4, wherein the single-ended correction circuit comprises a single-ended current starving inverter.

6. The duty cycle calibration circuit according to claim 5, wherein the single-ended current starving inverter comprises:
a pull-up block coupled to the control signal;
a pull-down block coupled to the control signal; and
an inverter coupled between the pull-up block and the pull-down block, configured to generate the output clock signal in response to the input clock signal.

7. The duty cycle calibration circuit according to claim 6, wherein the pull-up block comprises a PMOS transistor, having a gate terminal coupled to the control signal, a drain terminal coupled to the inverter, and a source terminal coupled to a power supply, and the pull-down block comprises a NMOS transistor, having a gate terminal coupled to the control signal, a drain terminal coupled to the inverter, and a source terminal coupled to a reference voltage terminal.

8. The duty cycle calibration circuit according to claim 4, wherein the single-ended detection circuit comprises a charge pump.

9. The duty cycle calibration circuit according to claim 8, wherein the charge pump comprises:
a charge storage device, configured to generate the control signal;
a first current source, configured to provide a charging current for the charge storage device;
a second current source, configured to provide a discharging current for the charge storage device; and
at least one logic gate, coupled between the first current source and second current source, and coupled to the charge storage device to generate the control signal in response to the output clock signal.

10. The duty cycle calibration circuit according to claim 9, wherein the at least one logic gate comprises an inverter.

11. The duty cycle calibration circuit according to claim 9, wherein the at least one logic gate comprises:
a first switch device, coupled between the first current source and the charge storage device, and switched under control of the output clock signal; and
a second switch device, coupled between the second current source and the charge storage device, and switched under control of the output clock signal.

12. The duty cycle calibration circuit according to claim 11, wherein the first switch device comprises a PMOS transistor, having a gate terminal coupled to the output clock signal, a drain terminal coupled to the charge storage device, and a source terminal coupled to the first current source, and the second switch device comprises a NMOS transistor, having a gate terminal coupled to the output clock signal, a drain terminal coupled to the charge storage device, and a source terminal coupled to the second current source.

13. The duty cycle calibration circuit according to claim 4, wherein the single-ended detection circuit comprises an RC circuit.

14. The duty cycle calibration circuit according to claim 5, wherein the single-ended correction circuit further comprises a buffer circuit, and the buffer circuit is coupled between the single-ended current starving inverter and the single-ended detection circuit.

15. The duty cycle calibration circuit according to claim 14, wherein the buffer circuit comprises an inverter.

16. A frequency synthesizer, comprising:
a frequency multiplier, configured to increase a frequency of a first clock signal to generate a second clock signal; and
a duty cycle calibration circuit, comprising:
a single-ended correction circuit, configured to adjust a duty cycle of the second clock signal, the single-ended correction circuit comprising:
a first slew rate controller, configured to adjust a rising slew rate of an output clock signal in response to a control signal;
a second slew rate controller, configured to adjust a falling slew rate of the output clock signal in response to the control signal; and
at least one logic gate coupled between the first slew rate controller and the second slew rate controller, configured to generate the output clock signal in response to the second clock signal; and
a single-ended detection circuit, configured to detect a duty cycle of the output clock signal by converting the duty cycle of the output clock signal to an average voltage to be served as the control signal.

17. The frequency synthesizer according to claim 16, wherein the single-ended detection circuit comprises a charge pump.

18. The frequency synthesizer according to claim 16, wherein the at least one logic gate comprises an inverter.

19. A frequency synthesizer, comprising:
a first duty cycle calibration circuit, comprising:
a first single-ended correction circuit, configured to adjust a duty cycle of an input clock signal, the single-ended correction circuit comprising:
a first slew rate controller, configured to adjust a rising slew rate of a first clock signal in response to a first control signal;
a second slew rate controller, configured to adjust a falling slew rate of the first clock signal in response to the first control signal; and
at least one logic gate coupled between the first slew rate controller and the second slew rate controller, configured to generate the first clock signal in response to the input clock signal; and
a first single-ended detection circuit, configured to detect a duty cycle of the first clock signal by converting the duty cycle of the first clock signal to an average voltage to be served as the first control signal; and
a frequency multiplier, configured to increase a frequency of the first clock signal to generate a second clock signal.

20. The frequency synthesizer according to claim 19, further comprises:
a second duty cycle calibration circuit, comprising:
a second single-ended correction circuit, configured to adjust a duty cycle of the second clock signal in response to a second control signal to generate an output clock signal, wherein the second single-ended correction circuit adjusts the duty cycle of the second clock signal by adjusting a slew rate of the output clock signal in response to the second control signal; and
a second single-ended detection circuit, configured to detect a duty cycle of the output clock signal by converting the duty cycle of the output clock signal to an average voltage to be served as the second control signal.
